(19) United States
(12) Patent Application Publication
(10) Pub. No.: US 2025/0311631 A1
(43) Pub. Date: Oct. 2, 2025

(54) THERMOELECTRIC CONVERSION MODULE

(71) Applicant: LINTEC Corporation, Tokyo (JP)

(72) Inventor: Nozomu MOTOHASHI, Tokyo (JP)

(73) Assignee: LINTEC Corporation, Tokyo (JP)

(21) Appl. No.: 19/093,371

(22) Filed: Mar. 28, 2025

(30) Foreign Application Priority Data
Mar. 29, 2024 (JP) 2024-058231

(51) Int. Cl. H10N 10/80; B32B 3/08; B32B 3/30; B32B 7/06; B32B 7/12; B32B 15/04; B32B 15/09; B32B 15/20; B32B 27/36

(52) U.S. Cl. CPC H10N 10/80; B32B 3/085; B32B 3/30; B32B 7/06; B32B 7/12; B32B 15/043; B32B 15/09; B32B 15/20; B32B 27/36; B32B 2250/40; B32B 2255/10; B32B 2255/26; B32B 2307/202; B32B 2405/00; B32B 2457/00

(57) ABSTRACT

Provided is a thermoelectric conversion module including a release sheet in which thermoelectric performance is not suppressed, a function as a support base material during a manufacturing process is provided and deformation and damage during conveyance and handling are suppressed. The thermoelectric conversion module includes: a thermoelectric element layer in which a P-type thermoelectric element and an N-type thermoelectric element are arranged alternately and electrically connected in series; a first conductive layer provided on a first surface of the thermoelectric element layer; a first pressure sensitive adhesive layer provided on a surface of the first conductive layer on a side opposite to a surface on the thermoelectric element layer side; and a first release sheet provided on a surface of the first pressure sensitive adhesive layer on a side opposite to a surface on the first conductive layer side. A curvature of the first release sheet is R1000 or greater when the first release sheet is cut to a length of 250 mm and suspended at a center in a length direction.

### CROSS-REFERENCE TO RELATED APPLICATION

This application is based upon and claims the benefit of priority from the prior Japanese Patent Application No. 2024-058231, filed on Mar. 29, 2024; the entire contents of which are incorporated herein by reference.

### TECHNICAL FIELD

The present invention relates to a thermoelectric conversion module.

### BACKGROUND ART

In the related art, one means for effectively utilizing energy is a device that directly inter-converts thermal energy and electrical energy using a thermoelectric conversion module having a thermoelectric effect such as a Seebeck effect or a Peltier effect.

As such a thermoelectric conversion module, use of a so-called π-type thermoelectric conversion element is known.

The π-type thermoelectric conversion element is configured with a basic unit in which a pair of electrodes spaced apart from each other are provided on a first substrate, for example, a lower surface of a P-type thermoelectric element is provided on a first electrode of the pair of electrodes and a lower surface of an N-type thermoelectric element is provided on a second electrode of the pair of electrodes, with the lower surface of the P-type thermoelectric element being spaced apart from the lower surface of the N-type thermoelectric element, and upper surfaces of both P-type thermoelectric element and N-type thermoelectric element are connected to a third electrode on a second substrate opposite to the first substrate. A plurality of such basic units are typically provided to achieve electrically serial connection and thermally parallel connection in both of the first and second substrates.

In recent years, to put a product or the like using a thermoelectric conversion module including such a π-type thermoelectric conversion element into practical use, there have been various demands for thinning of the thermoelectric conversion module, further improvement in thermoelectric performance, enhancement of reliability, including weather resistance and impact resistance, and the like. For example, Patent Document 1 discloses a thermoelectric conversion module using the above-described π-type thermoelectric conversion element. In the thermoelectric conversion module of Patent Document 1, a π-type thermoelectric conversion element is formed as an integrated body in which a gap portion consisting of a region between a chip of a P-type thermoelectric conversion material and a chip of an N-type thermoelectric conversion material, which are alternately spaced apart from each other, is filled with an insulator, thereby eliminating the need for a support base material with high thermal resistance as a support known in the related art.

### CITATION LIST

### Patent Literature

Patent Document 1: WO 2022/092177

### SUMMARY OF INVENTION

However, since Patent Document 1 does not include a support base material, there is a concern about deformation and damage during conveyance and handling due to a decrease in mechanical strength.

The present invention has been made in view of such circumstances, and an object thereof is to provide a thermoelectric conversion module including a release sheet in which thermoelectric performance is not suppressed, a function as a support base material during a manufacturing process is provided, and deformation and damage during conveyance and handling are suppressed.

As a result of diligent study in order to solve the above issue, the present inventors have found that when a thermoelectric conversion element in a thermoelectric conversion module is configured to include a first conductive layer provided on a first surface of a thermoelectric element layer, a first pressure sensitive adhesive layer provided on a surface of the first conductive layer on a side opposite to a surface on the thermoelectric element layer side, and a first release sheet provided on a surface of the first pressure sensitive adhesive layer on a side opposite to a surface on the first conductive layer side, and a curvature of the first release sheet is set to a specific value, the first release sheet functions as a support base material during a manufacturing process, and deformation and damage during conveyance and handling are suppressed, and have completed the present invention.

That is, the present invention provides the following [1] to [8].

[1] A thermoelectric conversion module including: a thermoelectric element layer in which a P-type thermoelectric element and an N-type thermoelectric element are arranged alternately and electrically connected in series; a first conductive layer provided on a first surface of the thermoelectric element layer; a first pressure sensitive adhesive layer provided on a surface of the first conductive layer on a side opposite to a surface on the thermoelectric element layer side; and a first release sheet provided on a surface of the first pressure sensitive adhesive layer on a side opposite to a surface on the first conductive layer side, in which a curvature of the first release sheet is R1000 or greater when the first release sheet is cut to a length of 250 mm and suspended at a center in a length direction.

[2] The thermoelectric conversion module according to [1], further including a second conductive layer provided on a second surface opposite to the first surface of the thermoelectric element layer.

[3] The thermoelectric conversion module according to [2], further including a second pressure sensitive adhesive layer provided on a surface of the second conductive layer on a side opposite to a surface on the thermoelectric element layer side.

[4] The thermoelectric conversion module according to [3], further including a second release sheet provided on a surface of the second pressure sensitive adhesive layer on a side opposite to a surface on the second conductive layer side.

[5] The thermoelectric conversion module according to [4], in which a release force of the first release sheet is greater or smaller than a release force of the second release sheet.

[6] The thermoelectric conversion module according to any one of [1] to [5], in which the first pressure sensitive adhesive layer is a pattern layer formed from a pressure sensitive adhesive composition, and a surface of the pattern layer having the same shape as that of a surface of the first conductive layer is in surface contact with the surface of the first conductive layer.

[7] The thermoelectric conversion module according to any one of [1] to [5], in which the first pressure sensitive adhesive layer is a solid layer formed from a pressure sensitive adhesive composition, and a surface of a partial region of the solid layer is in surface contact with a surface of the first conductive layer.

[8] The thermoelectric conversion module according to any one of [1] to [7], further including a gap portion consisting of a region between the P-type thermoelectric element layer and the N-type thermoelectric element layer.

According to the present invention, it is possible to provide a thermoelectric conversion module including a release sheet in which thermoelectric performance is not suppressed, a function as a support base material during a manufacturing process is provided, and deformation and damage during conveyance and handling are suppressed.

### BRIEF DESCRIPTION OF DRAWINGS

FIG. 1 is a cross-sectional configuration view of an embodiment (configuration A) of a thermoelectric conversion module according to the present invention.

FIG. 2 is a cross-sectional configuration view of another embodiment (configuration C) of the thermoelectric conversion module according to the present invention.

### DESCRIPTION OF EMBODIMENTS

### Thermoelectric Conversion Module

A thermoelectric conversion module of the present invention includes: a thermoelectric element layer in which a P-type thermoelectric element and an N-type thermoelectric element are arranged alternately and electrically connected in series; a first conductive layer provided on a first surface of the thermoelectric element layer; a first pressure sensitive adhesive layer provided on a surface of the first conductive layer on a side opposite to a surface on the thermoelectric element layer side; and a first release sheet provided on a surface of the first pressure sensitive adhesive layer on a side opposite to a surface on the first conductive layer side. A curvature of the first release sheet is R1000 or greater when the first release sheet is cut to a length of 250 mm and suspended at a center in a length direction.

In the configuration of the thermoelectric conversion module according to the present invention, the first conductive layer provided on the first surface of the thermoelectric element layer, the first pressure sensitive adhesive layer provided on the surface of the first conductive layer on the side opposite to the surface on the thermoelectric element layer side, and the first release sheet provided on the surface of the first pressure sensitive adhesive layer on the side opposite to the surface on the first conductive layer side are included, and the curvature of the first release sheet is set to a specific value. As a result, the first release sheet functions as a support base material during a manufacturing process, and deformation and damage during conveyance and handling can be suppressed. In addition, in the thermoelectric conversion module after the first release sheet is removed, since the support base material is removed, it is possible to facilitate the thinning.

In the present specification, the preferred provisions can be selected as desired, and combinations of the preferred provisions are more preferable.

In the present specification, the description “from XX to YY” means “XX or higher and YY or lower” or “XX or greater and YY or less”.

In the present specification, the lower and upper limits of a preferable numerical range (for example, a range of content) described in series can each be independently combined. For example, from the description “preferably from 10 to 90, and more preferably from 30 to 60”, the “preferred lower limit (10)” and the “more preferred upper limit (60)” can be combined as “from 10 to 60”.

In the present specification, the “solid layer” refers to a “layer having a surface continuously extending in a direction perpendicular to a thickness direction of the layer without gaps on the way”.

A thermoelectric conversion module of the present invention includes: a thermoelectric element layer in which a P-type thermoelectric element and an N-type thermoelectric element are arranged alternately and electrically connected in series; a first conductive layer provided on a first surface of the thermoelectric element layer; a first pressure sensitive adhesive layer formed of a solid layer provided on a surface of the first conductive layer on a side opposite to a surface on the thermoelectric element layer side; and a first release sheet provided on a surface of the first pressure sensitive adhesive layer on a side opposite to a surface on the first conductive layer side. In addition, a curvature of the first release sheet is R1000 or greater when the first release sheet is cut to a length of 250 mm and suspended at a center in a length direction.

In one aspect of the present invention, a second conductive layer is preferably provided on a second surface opposite to the first surface of the thermoelectric element layer.

In addition, a second pressure sensitive adhesive layer is preferably provided on a surface of the second conductive layer on a side opposite to a surface on the thermoelectric element layer side.

Furthermore, a second release sheet is preferably provided on a surface of the second pressure sensitive adhesive layer on a side opposite to a surface on the second conductive layer side.

In one aspect, the first pressure sensitive adhesive layer is a solid layer formed from a pressure sensitive adhesive composition, and a surface of a partial region of the solid layer is preferably in surface contact with a surface of the first conductive layer.

In one aspect of the present invention, a gap portion consisting of a region between the P-type thermoelectric element layer and the N-type thermoelectric element layer may be included. By providing the gap portion, the thermal resistance is set to be high, and the thermoelectric performance of the thermoelectric conversion module can be maintained high.

As another embodiment, a gap portion consisting of a region between the P-type thermoelectric element layer and the N-type thermoelectric element layer need not be included. That is, the gap portion may be filled with a pressure sensitive adhesive of the first or second pressure sensitive adhesive layer. In this case, strength of the thermoelectric conversion module can be enhanced.

When a ratio V of the gap portion in a longitudinal section consisting of the region between the P-type thermoelectric element and the N-type thermoelectric element is defined by the following formula, the ratio V of the gap portion is 0 to 1.0, preferably more than 0 and 1.0 or less, more preferably 0.5 to 1.0, and particularly preferably 0.8 to 1.0.

V=1−[(the maximum value of the filling distance in the thickness direction of the thermoelectric element layer in the first pressure sensitive adhesive layer from the surface of the first conductive layer on the side opposite to the surface on the thermoelectric element layer side)/(the thickness of the first conductive layer+the thickness of the thermoelectric element layer)]

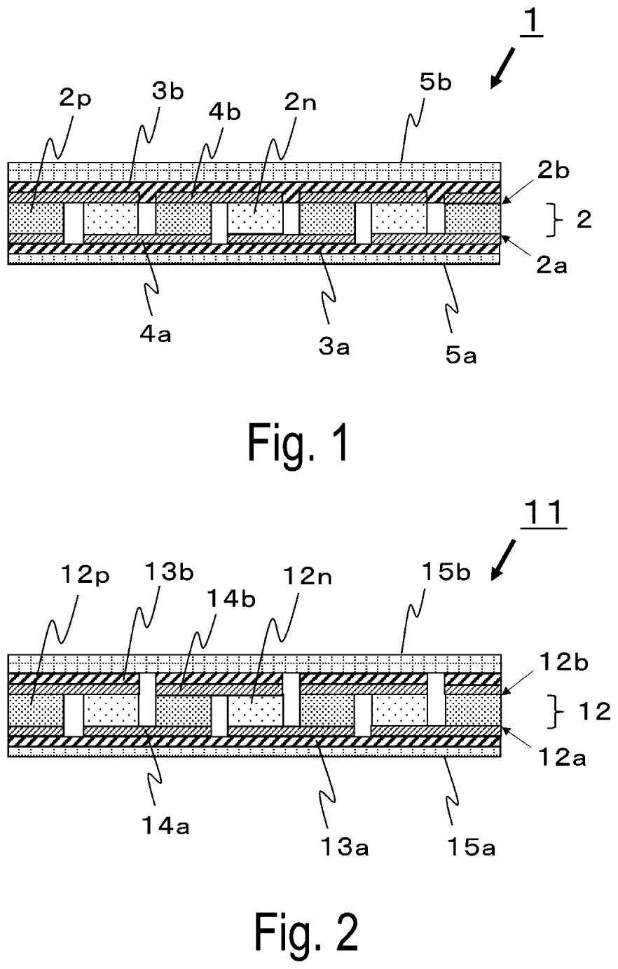

FIG. 1 is a cross-sectional configuration view showing an embodiment (configuration A) of a thermoelectric conversion module of the present invention. A thermoelectric conversion module 1 includes a thermoelectric element layer 2 in which P-type thermoelectric elements 2p and N-type thermoelectric elements 2n are arranged alternately and electrically connected in series, a first conductive layer 4b provided on a first surface 2b of the thermoelectric element layer 2, a first pressure sensitive adhesive layer 3b formed of a solid layer provided on a surface of the first conductive layer 4b on a side opposite to a surface of the thermoelectric element layer 2 side, a first release sheet 5b provided on a surface of the first pressure sensitive adhesive layer 3b on a side opposite to a surface of the first conductive layer 4b side, a second conductive layer 4a provided on a second surface 2a of the thermoelectric element layer 2 opposite to the first surface 2b of the thermoelectric element layer 2, a second pressure sensitive adhesive layer 3a formed of a solid layer provided on a surface of the second conductive layer 4a on a side opposite to a surface of the thermoelectric element layer 2 side, and a second release sheet 5a provided on a surface of the second pressure sensitive adhesive layer 3a on a side opposite to a surface of the second conductive layer 4a side. Here, a curvature of the first release sheet 5b is R1000 or greater when the first release sheet 5b is cut to a length of 250 mm and suspended at a center in a length direction.

In another aspect, the first pressure sensitive adhesive layer is a pattern layer formed from a pressure sensitive adhesive composition, and a surface of the pattern layer having the same shape as that of a surface of the first conductive layer is preferably in surface contact with the surface of the first conductive layer. The first pressure sensitive adhesive layer is a pattern layer having the same shape as that of the surface of the first conductive layer, and thus, for example, a short circuit between adjacent first conductive layers and a decrease in thermoelectric performance can be suppressed. In addition, for example, particles with high thermal conductivity can be contained in the pattern layer, which leads to suppression of thermal resistance.

FIG. 2 is a cross-sectional configuration view of another embodiment (configuration C) of the thermoelectric conversion module according to the present invention.

A thermoelectric conversion module 11 includes a thermoelectric element layer 12 in which P-type thermoelectric elements 12p and N-type thermoelectric elements 12n are arranged alternately and electrically connected in series, a first conductive layer 14b provided on a first surface 12b of the thermoelectric element layer 12, a first pressure sensitive adhesive layer 13b provided on a surface of the first conductive layer 14b on a side opposite to a surface of the thermoelectric element layer 12 side, the first pressure sensitive adhesive layer 13b being in surface contact with the first conductive layer 14b on a surface of a pattern layer having the same shape as the first conductive layer 14b, a first release sheet 15b provided on a surface of the first pressure sensitive adhesive layer 13b on a side opposite to a surface of the first conductive layer 14b side, a second conductive layer 14a provided on a second surface 12a of the thermoelectric element layer 12 opposite to the first surface 12b of the thermoelectric element layer 12, a second pressure sensitive adhesive layer 13a formed of a solid layer provided on a surface of the second conductive layer 14a on a side opposite to a surface of the thermoelectric element layer 12 side, and a second release sheet 15a provided on a surface of the second pressure sensitive adhesive layer 13a on a side opposite to a surface of the second conductive layer 14a side. Here, a curvature of the first release sheet 15b is R1000 or greater when the first release sheet 15b is cut to a length of 250 mm and suspended at a center in a length direction.

In addition, as another aspect of FIG. 2, the thermoelectric conversion module may be one in which the second pressure sensitive adhesive layer is also a pattern layer having the same shape as the second conductive layer 14a, and the second pressure sensitive adhesive layer and the second conductive layer 14a are laminated in a manner that patterns coincide with each other.

A curvature of the first release sheet is R1000 or greater when the first release sheet is cut to a length of 250 mm and suspended at a center in a length direction. Here, R is a radius, 1000 has a unit of mm, and this means that the first release sheet having a length of 250 mm forms an arc with a radius of 1 m. In addition, this means that the larger the value of R, the more gentle arc the sheet forms.

R is preferably 1050 mm or more, more preferably 1100 mm or more, and even more preferably 1200 mm to 2000 mm. When R of the first release sheet falls within this range, handleability during a manufacturing process can be ensured.

It is preferable that the release force of the first release sheet be different from the release force of the second release sheet, and the release force of the first release sheet be greater or smaller than the release force of the second release sheet. When the first release sheet and the second release sheet have a difference in release force, the release sheet with a smaller release force can be first selectively removed, and damage to the thermoelectric conversion module at the time of removing can be reduced. In addition, when the release force of the first release sheet is greater than the release force of the second release sheet, handleability is easily secured, for example, until the second release sheet of the thermoelectric conversion module of the present invention is removed and the second pressure sensitive adhesive layer is attached to an adherend, followed by removing of the first release sheet of the thermoelectric conversion module and attachment of the first pressure sensitive adhesive layer to another adherend.

On the other hand, when the release force of the first release sheet is smaller than the release force of the second release sheet, it becomes easier to select a second release sheet with a smaller curvature and to facilitate roll storage or the like of a long thermoelectric conversion module.

Each of the first release sheet and the second release sheet preferably includes a release base material and a release agent layer formed by applying a release agent on the release base material. In addition, the release sheet may have a release agent layer only on one surface of the release base material, or may have release agent layers on both surfaces of the release base material. Examples of the release base material include a paper base material, laminated paper produced by laminating a thermoplastic resin such as polyethylene on the paper base material, and a plastic film. Examples of the paper base material include glassine paper, coated paper, cast-coated paper, and the like. Examples of the plastic film include polyester films such as polyethylene terephthalate, polybutylene terephthalate, and polyethylene naphthalate; and polyolefin films such as polypropylene and polyethylene. Examples of the release agent include olefin-based resins, rubber-based elastomers (for example, butadiene-based resins, isoprene-based resins), long-chain alkyl-based resins, alkyd-based resins, fluorine-based resins, and silicone-based resins.

The release force of the first release sheet and the second release sheet
can be usually controlled by varying the composition of the release agent layer in the release sheet in contact with the pressure sensitive adhesive layer.

The release force of the first release sheet is not particularly limited and is preferably from 30 to 300 mN/25 mm, and more preferably from 50 to 200 mN/25 mm. The release force of the first release sheet is more preferably from 80 to 150 mN/25 mm.

A thickness of the release agent layer of the first release sheet is not particularly limited; however, when the release agent layer is formed by applying a solution containing a release agent, the thickness of the release agent layer is preferably from 0.01 to 2.0 μm, and more preferably from 0.03 to 1.0 μm.

When a plastic film is used as the release base material, a thickness of the plastic film is preferably from 60 to 300 μm, more preferably from 80 to 200 μm, and even more preferably from 90 to 140 μm. When the thickness of the release base material falls within this range, the release base material can function as a support base material during the manufacturing process and is excellent in handleability.

The release force of the second release sheet is not particularly limited and is preferably from 40 to 1800 mN/25 mm, and more preferably from 150 to 1200 mN/25 mm. The release force of the second release sheet is more preferably from 580 to 950 mN/25 mm.

A thickness of the release agent layer of the second release sheet is not particularly limited; however, when the release agent layer is formed by applying a solution containing a release agent, the thickness of the release agent layer is preferably from 0.01 to 2.0 μm, and more preferably from 0.03 to 1.0 μm.

When a plastic film is used as the release base material, a thickness of the plastic film is preferably from 10 to 100 μm, more preferably from 20 to 80 μm, and even more preferably from 30 to 55 μm.

The difference in release force between the first release sheet and the second release sheet is preferably from 10 to 1500 mN/25 mm, more preferably from 100 to 1000 mN/25 mm, and even more preferably from 500 to 800 mN/25 mm. Within the above range, both the release sheets can be easily removed without causing damage to the thermoelectric conversion module.

The release force of the first release sheet and the release force of the second release sheet are each measured in accordance with JIS Z0237:2009.

The pressure sensitive adhesive layer is not particularly limited as long as it enables lamination of a thermoelectric element layer, only needs to contain a pressure sensitive adhesive resin, and may contain, if desired, additives for pressure sensitive adhesives such as a cross-linking agent, a tackifier, a polymerizable compound, and a polymerization initiator, a silane coupling agent, an antistatic agent, an antioxidant, an ultraviolet absorber, a light stabilizer, a softener, a filler, a refractive index adjuster, a colorant, and the like.

Examples of the pressure sensitive adhesive resin include acrylic resins, epoxy-based resins, urethane-based resins, rubber-based resins such as polyisobutylene-based resins, polyester-based resins, olefin-based resins, silicone-based resins, and polyvinyl ether-based resins.

Among these, from the viewpoint of satisfying the range of the specific resistance of the first pressure sensitive adhesive layer described later, an acrylic resin, an epoxy-based resin, a rubber-based resin, or an olefin-based resin is preferable.

The specific resistance of the first pressure sensitive adhesive layer is preferably 1.0×10¹² Ω·cm or more, more preferably 5.0×10¹² Ω·cm or more, and even more preferably 1.0×10¹³ Ω·cm or more. When the specific resistance of the first pressure sensitive adhesive layer falls within this range, the insulating property of the first pressure sensitive adhesive layer is ensured, and a short circuit between adjacent first conductive layers can be suppressed.

The pressure sensitive adhesive layer may be formed from a pressure sensitive adhesive composition containing a pressure sensitive adhesive resin by a well-known method. Examples of the method for forming the pressure sensitive adhesive layer include a screen printing method, a spin coating method, a spray coating method, a bar coating method, a knife coating method, a roll coating method, a roll knife coating method, a blade coating method, a die coating method, and a gravure coating method.

Among them, a screen printing method using a screen plate corresponding to a desired pattern shape, a gravure coating method using a roll having an uneven shape corresponding to a desired pattern shape, or the like may be exemplified as a forming method of patterning a pressure sensitive adhesive layer, and a patterned pressure sensitive adhesive layer may be formed by coating a pressure sensitive adhesive composition.

### First Conductive Layer and Second Conductive Layer

Regarding the first conductive layer and the second conductive layer (hereinafter, sometimes simply referred to as “conductive layer”) used in the present invention, the first conductive layer is preferably at least one selected from the group consisting of a metal electrode layer, a metal oxide electrode layer, and a conductive resin layer.

Examples of the metal used for the metal electrode layer include aluminum, molybdenum, cobalt, zirconium, tin, niobium, iron, chromium, tantalum, titanium, gold, platinum, vanadium, manganese, nickel, copper, hafnium, tungsten, iridium, zinc, indium, palladium, stainless steel, neodymium, and silver, or alloys thereof.

Examples of the metal oxide used for the metal oxide electrode layer include indium-tin oxide (ITO), indium-zinc oxide (IZO), aluminum-zinc oxide (AZO), gallium-zinc oxide (GZO), indium-gallium-zinc oxide (IGZO), niobium oxide, titanium oxide, and tin oxide, and one or more of these can be used. Among them, indium-tin oxide (ITO) is particularly preferable from the viewpoints of surface resistivity and heat resistance.

Examples of the conductive resin layer include a conductive paste formed from a conductive composition containing conductive particles. As the conductive paste, a paste in which conductive particles such as metal particles, carbon particles, or ruthenium oxide particles are dispersed in a solvent including a binder can be used. As the material of the metal particles, silver, copper, gold, or the like is preferable from the viewpoint of conductivity, and silver, copper, nickel, iron, cobalt, or the like is preferable from the viewpoint of cost.

Examples of methods for forming the conductive layer include a method in which a conductive layer having no pattern formed on a pressure sensitive adhesive layer is provided, and then processed into a predetermined pattern shape by a known physical treatment mainly using a photolithography method, a chemical treatment, or a combination thereof, or a method in which a pattern of the conductive layer is directly formed by a screen printing method, an inkjet method, or the like using a conductive paste formed from a conductive composition including the conductive particles.

Examples of methods for forming a conductive layer having no pattern formed thereon include dry processes, including physical vapor deposition (PVD) methods such as vacuum vapor deposition, sputtering, and ion plating or chemical vapor deposition (CVD) methods such as thermal CVD and atomic layer deposition (ALD); or wet processes including various coating methods, such as dip coating, spin coating, spray coating, gravure coating, die coating, and doctor blade coating, and electrodeposition methods; silver salt methods; electrolytic plating; electroless plating; and layering of metal foils. The method is appropriately selected according to the material for the conductive layer.

From the perspective of maintaining thermoelectric performance, the conductive layer used in the present invention is required to exhibit high electrical conductivity and high thermal conductivity, and therefore use of electrodes formed by a plating method or a vacuum film formation method is more preferable. Since high electrical conductivity and high thermal conductivity can be easily achieved, vacuum film formation methods such as vacuum vapor deposition and sputtering, electrolytic plating; and electroless plating are preferred. A pattern can be easily formed through a hard mask such as a metal mask depending on dimensions of a pattern to be formed and required dimensional accuracy.

The thicknesses of the first conductive layer and the second conductive layer are each independently preferably from 10 nm to 200 μm, more preferably from 1 μm to 100 μm, and even more preferably from 10 μm to 60 μm. If the thicknesses of the respective conductive layers fall within the range described above, electrical conductivity is high, resistance is low, and sufficient strength as a conductive layer is achieved.

### Thermoelectric Element

The thermoelectric element used in the present invention is not particularly limited, and may be a thin film containing a thermoelectric semiconductor.

From the viewpoints of flexibility, thin profile, and thermoelectric performance, the thermoelectric element is preferably formed from a thermoelectric semiconductor composition containing thermoelectric semiconductor particles, and a resin, and, if desired, one or both of an ionic liquid and an inorganic ionic compound.

The thermoelectric semiconductor particles used in the thermoelectric element are preferably prepared by pulverizing a thermoelectric semiconductor material to a predetermined size by a micropulverizer or the like and then used as thermoelectric semiconductor particles.

A particle size of the thermoelectric semiconductor particles is preferably from 10 nm to 100 μm, more preferably from 20 nm to 50 μm, and even more preferably from 30 nm to 30 μm.

An average particle size of the thermoelectric semiconductor particles was measured using a laser diffraction particle size analyzer (Mastersizer 3000 available from Malvern Panalytical Ltd.), and the median of the particle size distribution is used as the average particle size.

The thermoelectric semiconductor material constituting the P-type thermoelectric element and the N-type thermoelectric element in the thermoelectric element used in the present invention is not particularly limited as long as the thermoelectric semiconductor material is a material that can generate thermoelectromotive force by providing a temperature difference. For example, bismuth-tellurium-based thermoelectric semiconductor materials such as P-type bismuth telluride and N-type bismuth telluride; telluride-based thermoelectric semiconductor materials such as GeTe and PbTe; antimony-tellurium-based thermoelectric semiconductor materials; zinc-antimony-based thermoelectric semiconductor materials such as ZnSb, Zn₃Sb₂, and Zn₄Sb₃; silicon-germanium-based thermoelectric semiconductor materials such as SiGe; bismuth selenide-based thermoelectric semiconductor materials such as Bi₂Se₃; silicide-based thermoelectric semiconductor materials such as β-FeSi₂, CrSi₂, MnSi_{1.73}, and Mg₂Si; oxide-based thermoelectric semiconductor materials; Heusler materials such as FeVAl, FeVAlSi, and FeVTiAl; and sulfide-based thermoelectric semiconductor materials such as TiS₂ are used.

The content of the thermoelectric semiconductor particles in the thermoelectric semiconductor composition is preferably from 30 to 99 mass %. More preferably, the content is from 50 to 96 mass %, and even more preferably from 70 to 95 mass %. If the content of the thermoelectric semiconductor particles is within the range described above, the Seebeck coefficient (absolute value of the Peltier coefficient) is large, a decrease in electrical conductivity is suppressed, and only thermal conductivity is reduced, and therefore a film exhibiting a high thermoelectric performance and having sufficient film strength and flexibility is produced. Thus, the content of the thermoelectric semiconductor particles is preferably within the range described above.

Furthermore, the thermoelectric semiconductor particles are preferably subjected to an annealing treatment (hereinafter, also referred to as an “annealing treatment A”). When the thermoelectric semiconductor particles are subjected to the annealing treatment A, the crystallinity of the thermoelectric semiconductor particles is improved, and a surface oxide film of the thermoelectric semiconductor particles is removed, and therefore the Seebeck coefficient (absolute value of the Peltier coefficient) of the thermoelectric element layer increases, and the thermoelectric performance index can be further improved.

### Resin

The resin used in the present invention has a function of physically bonding the thermoelectric semiconductor particles together, and can increase the flexibility of the thermoelectric conversion module and facilitate the formation of a thin film through coating or the like.

The resin is preferably a heat-resistant resin or a binder resin.

When crystal growth of the thermoelectric semiconductor particles is caused by subjecting the thin film formed from the thermoelectric semiconductor composition to an annealing treatment or the like, the physical properties such as mechanical strength and thermal conductivity of the heat-resistant resin as a resin are maintained without being impaired.

From the perspective of further increasing heat resistance and not adversely affecting crystal growth of the thermoelectric semiconductor particles in the thin film, the heat-resistant resin is preferably a polyamide resin, a polyamide-imide resin, a polyimide resin, or an epoxy resin, and from the perspective of excelling in flexibility, the heat-resistant resin is more preferably a polyamide resin, a polyamide-imide resin, or a polyimide resin.

The heat-resistant resin preferably has a decomposition temperature of 300° C. or higher. If the decomposition temperature is within the range described above, flexibility can be maintained without loss of function as a binder even when the thin film formed from the thermoelectric semiconductor composition is subjected to annealing treatment as described below.

The content of the heat-resistant resin in the thermoelectric semiconductor composition is preferably from 0.1 to 40 mass %, more preferably from 1 to 20 mass %, and even more preferably from 2 to 15 mass %. When the content of the heat-resistant resin is within the range described above, the heat-resistant resin functions as a binder of the thermoelectric semiconductor particles and facilitates the formation of a thin film, and therefore a film having both high thermoelectric performance and film strength is produced.

The binder resin is preferably a resin in which 90 mass % or more decomposes at the firing (annealing) temperature or higher, more preferably a resin in which 95 mass % or more decomposes at the firing temperature or higher, and particularly preferably a resin in which 99 mass % or more decomposes at the firing temperature or higher.

When a resin in which 90 mass % or more decomposes at the firing (annealing) temperature or higher, that is, a resin that decomposes at a lower temperature than the heat-resistant resin described above, is used as the binder resin, the binder resin decomposes through firing, and therefore the content of the binder resin serving as an insulating component contained in the fired product is reduced, and crystal growth of the thermoelectric semiconductor particles in the thermoelectric semiconductor composition is promoted. Thus, voids in the thermoelectric element can be reduced, and the filling ratio can be improved.

Note that whether a resin decomposes at or above a predetermined amount (for example, 90 mass %) at or above the firing (annealing) temperature is determined by measuring the mass loss rate (a value calculated by dividing the mass after decomposition by the mass before decomposition) at the firing (annealing) temperature through thermogravimetry (TG).

A thermoplastic resin or a curable resin can be used as the binder resin. Examples of thermoplastic resin include polyolefin-based resins such as polyethylene, polypropylene, polyisobutylene, and polymethylpentene; polycarbonates; thermoplastic polyester resins such as polyethylene terephthalate and polyethylene naphthalate; polyvinyl polymers such as polystyrene, acrylonitrile-styrene copolymer, polyvinyl acetate, ethylene-vinyl acetate copolymer, vinyl chloride, polyvinyl pyridine, polyvinyl alcohol, and polyvinyl pyrrolidone; polyurethanes; and cellulose derivatives such as ethyl cellulose. Examples of the curable resin include thermosetting resins and photocurable resins. Examples of thermosetting resins include epoxy resins and phenol resins. Examples of photocurable resins include photocurable acrylic resins, photocurable urethane resins, and photocurable epoxy resins. One of these may be used alone, or two or more may be used in combination.

The binder resin is appropriately selected according to the temperature of the firing (annealing) treatment of the thermoelectric semiconductor particles in the firing (annealing) treatment process. From the viewpoint of electrical resistivity of the thermoelectric semiconductor particles in the thermoelectric element, the firing (annealing) treatment is preferably implemented at a temperature equal to or higher than the final decomposition temperature of the binder resin.

In the present specification, the “final decomposition temperature” refers to a temperature at which the mass loss rate at the firing (annealing) temperature as determined through thermogravimetry (TG) is 100% (mass after decomposition is 0% of the mass before decomposition).

The final decomposition temperature of the binder resin is typically from 150 to 600° C., preferably from 240 to 360° C. When a binder resin having a final decomposition temperature within this range is used, the binder resin functions as a binder for the thermoelectric semiconductor particles, and formation of a thin film is facilitated when printing.

The content of the binder resin in the thermoelectric semiconductor composition is from 0.1 to 40 mass %, preferably from 0.5 to 10 mass %. When the content of the binder resin falls within the range described above, the electrical resistivity of the thermoelectric semiconductor particles in the thermoelectric element can be reduced.

The content of the binder resin in the thermoelectric element is preferably from 0 to 10 mass %, more preferably from 0 to 5 mass %, and particularly preferably from 0 to 1 mass %. When the content of the binder resin in the thermoelectric conversion material falls within the range described above, the electrical resistivity of the thermoelectric semiconductor particles in the thermoelectric element can be reduced.

### Ionic Liquid

The ionic liquid that may be contained in the thermoelectric semiconductor composition is a molten salt prepared by combining a cation and an anion and is a salt that can be present as a liquid in any temperature region in −50° C. or higher and lower than 400° C. In other words, the ionic liquid is an ionic compound having a melting point in the range of −50° C. or higher and lower than 400° C. The melting point of the ionic liquid is preferably −25° C. or higher and 200° C. or lower, and more preferably 0° C. or higher and 150° C. or lower. Because the ionic liquid has characteristics such as having a significantly low vapor pressure and being nonvolatile, having excellent thermal stability and electrochemical stability, having a low viscosity, and having a high ionic conductivity, the ionic liquid can effectively suppress reduction of the electrical conductivity between the thermoelectric semiconductor materials as a conductivity aid. Furthermore, the ionic liquid exhibits high polarity based on the aprotic ionic structure and has excellent compatibility with the heat-resistant resin, thereby allowing the electrical conductivity of the thermoelectric element to be made uniform.

As the ionic liquid, a known or commercially available ionic liquid can be used. Examples thereof include those formed from nitrogen-containing cyclic cation compounds and derivatives thereof, such as pyridinium, pyrimidinium, pyrazolium, pyrrolidinium, piperidinium, and imidazolium; tetraalkylammonium-based amine cations and derivatives thereof; phosphine cations and derivatives thereof, such as phosphonium, trialkylsulfonium, and tetraalkylphosphonium; cation components, such as lithium cation and derivatives thereof; and anion components, such as Cl⁻, Br⁻, I⁻, AlCl₄⁻, Al₂Cl₇⁻, BF₄⁻, PF₆⁻, ClO₄⁻, NO₃⁻, CH₃COO⁻, CF₃COO⁻, CH₃SO₃⁻, CF₃SO₃⁻, (FSO₂)₂N⁻, (CF₃SO₂)₂N⁻, (CF₃SO₂)₃C⁻, AsF₆⁻, SbF₆⁻, NbF₆⁻, TaF₆⁻, F(HF)ₙ⁻, (CN)₂N⁻, C₄F₉SO₃⁻, (C₂F₅SO₂)₂N⁻, C₃F₇COO⁻, and (CF₃SO₂)(CF₃CO)N⁻.

In the ionic liquid described above, from the perspective of high temperature stability, compatibility between the thermoelectric semiconductor particles and the resin, suppression of reduction of the electrical conductivity between the thermoelectric semiconductor particles, and the like, the cation component of the ionic liquid preferably contains at least one type selected from the group consisting of pyridinium cations and derivatives thereof and imidazolium cations and derivatives thereof.

Furthermore, the ionic liquid described above preferably has a decomposition temperature of 300° C. or higher. When the decomposition temperature is in the range described above, as described below, even in a case where a thin film formed from the thermoelectric semiconductor composition is subjected to annealing treatment, the effect as a conductivity aid can be maintained.

The content of the ionic liquid in the thermoelectric semiconductor composition is preferably from 0.01 to 50 mass %, more preferably from 1.0 to 20 mass %. When the content of the ionic liquid is in the range described above, reduction of the electrical conductivity is effectively suppressed, and a film having a high thermoelectric performance can be produced.

### Preparation Method of Thermoelectric Semiconductor Composition

The method for preparing the thermoelectric semiconductor composition is not particularly limited, and the thermoelectric semiconductor composition may be prepared by, for example, adding the thermoelectric semiconductor particles, the resin, and, if desired, the ionic liquid, the inorganic ionic compound, the other additives and also a solvent, and mixing and dispersing the various components through a well-known method such as an ultrasonic homogenizer, a spiral mixer, a planetary mixer, a disperser, or a hybrid mixer.

Examples of the solvent include solvents such as toluene, ethyl acetate, methyl ethyl ketone, alcohol, tetrahydrofuran, methyl pyrrolidone, and ethyl cellosolve. One type of these solvents may be used alone, or two or more types of these solvents may be mixed and used. As the solid content concentration of the thermoelectric semiconductor composition, the composition is only required to have a viscosity adequate for coating, and the solid content concentration is not particularly limited.

The thermoelectric element formed from the thermoelectric semiconductor composition is not particularly limited; however, the thermoelectric element can be formed, for example, by producing a coating film by coating the thermoelectric semiconductor composition onto a base material such as glass, alumina, silicon, or a resin film, or onto a base material on a side on which a below-described sacrificial layer is formed, drying the coating film, and then separating the coating film from the base material as appropriate. With such formation, numerous thermoelectric elements can be easily produced at low costs. As the resin film, a film having heat resistance is preferred, and a film formed from a polyamide resin, a polyamide-imide resin, a polyimide resin, or the like is preferable.

The method of applying the thermoelectric semiconductor composition onto the base material to produce a thermoelectric element is not particularly limited, and examples thereof include known methods such as screen printing, flexographic printing, gravure printing, spin coating, dip coating, die coating, spray coating, bar coating, and doctor blade coating. When the coating film is to be formed in a pattern, a method such as screen printing or slot die coating by which the pattern can be easily formed using a screen plate having the desired pattern is preferably used.

The resulting coating film is then dried to form a thermoelectric element. As the drying method, a well-known drying method can be used, such as hot air drying, heated roll drying, and infrared irradiation. The heating temperature is typically from 80 to 150° C., and while the heating time differs depending on the heating method, the heating time is typically from a few seconds to tens of minutes.

Furthermore, when a solvent is used in the preparation of the thermoelectric semiconductor composition, the heating temperature is not particularly limited as long as the temperature is within a temperature range in which the solvent used can be completely dried.

The thickness of the thin film formed from the thermoelectric semiconductor composition is not particularly limited, but from the perspective of thermoelectric performance and film strength, the thickness of the thin film is preferably from 100 nm to 1000 μm, more preferably from 300 nm to 600 μm, and even more preferably from 5 to 400 μm.

The thermoelectric element as a thin film including the thermoelectric semiconductor composition is preferably further subjected to an annealing treatment (hereinafter, sometimes referred to as “annealing treatment B”). By subjecting the thermoelectric element layer to the annealing treatment B, the thermoelectric performance can be stabilized, crystal growth of the thermoelectric semiconductor particles in the thin film can be promoted, and the thermoelectric performance can be further improved. The annealing treatment B is not particularly limited, but is ordinarily implemented in an atmosphere with the gas flow rate controlled, including an inert gas atmosphere such as nitrogen or argon or a reducing gas atmosphere, or is implemented under vacuum conditions, at a temperature ranging from 100 to 800° C. for several minutes to several tens of hours. Furthermore, in the annealing treatment B, the thermoelectric semiconductor composition may be pressed to increase the density of the thermoelectric semiconductor composition.

### Method for Manufacturing Thermoelectric Conversion Module

A method for manufacturing a thermoelectric conversion module according to the present invention includes the following steps (a) to (j):
(a) preparing a P-type thermoelectric element and an N-type thermoelectric element;
(b) forming a first pressure sensitive adhesive layer on a release layer of a first release sheet;
(c) forming a first conductive layer on the first pressure sensitive adhesive layer;
(d) forming a solder material layer on the first conductive layer;
(e) placing the P-type thermoelectric element and the N-type thermoelectric element on the solder material layer to produce a thermoelectric conversion module intermediate 1;
(f) forming a second pressure sensitive adhesive layer on a release layer of a second release sheet;
(g) forming a second conductive layer on the second pressure sensitive adhesive layer;
(h) forming a solder material layer on the second conductive layer to produce a thermoelectric conversion module intermediate 2;
(i) producing a thermoelectric conversion module precursor by arranging the thermoelectric conversion module intermediate 1 and the thermoelectric conversion module intermediate 2 to face each other and bonding them together; and
(j) forming a thermoelectric conversion module by subjecting the thermoelectric conversion module precursor to a reflow treatment and joining the thermoelectric conversion module intermediate 1 and the thermoelectric conversion module intermediate 2 via the solder material layer.

Below, the steps included in the method for manufacturing a thermoelectric conversion module will be described sequentially.

In the following description, the step (a) may be referred to as “thermoelectric element preparation step”, the steps (b) and (f) may be referred to as “pressure sensitive adhesive layer forming step”, the steps (c) and (g) may be referred to as “conductive layer forming step”, the step (d) may be referred to as “solder material layer forming step”, the step (e) may be referred to as “thermoelectric element placing step”, the step (h) may be referred to as “thermoelectric conversion module intermediate 2 production step”, the step (i) may be referred to as “thermoelectric conversion module precursor production step”, and the step (j) may be referred to as “reflow treatment step”.

### Thermoelectric Element Preparation Step

The thermoelectric element preparation step is the step (a) of the method for manufacturing a thermoelectric conversion module of the present invention. For example, a sacrificial layer to be described later is formed on a base material such as glass, a coating film of a thermoelectric element is formed on the resulting sacrificial layer by the method described above, and then an annealing treatment (according to the conditions of the annealing treatment B) is performed to produce a thermoelectric element. The resulting thermoelectric element is removed from the sacrificial layer on the base material, thereby preparing thermoelectric elements as a plurality of individual pieces.

When the sacrificial layer is used, the thermoelectric element formed on the base material such as glass can easily be removed from the glass or the like after the annealing treatment B. As the sacrificial layer, a resin such as polymethyl methacrylate or polystyrene, or a release agent such as a fluorine-based release agent or a silicone-based release agent can be used. The formation of the sacrificial layer is not particularly limited, and the sacrificial layer can be formed by a well-known method such as flexographic printing or spin coating.

### Pressure Sensitive Adhesive Layer Forming Step

The pressure sensitive adhesive layer forming step is a step of forming the first pressure sensitive adhesive layer on the release layer of the first release sheet in the step (b) of the method for manufacturing a thermoelectric conversion module of the present invention, and is also a step of forming the second pressure sensitive adhesive layer on the release layer of the second release sheet in the step (f). For example, this step is a step of applying a pressure sensitive adhesive resin onto a release sheet to form a pressure sensitive adhesive layer.

The pressure sensitive adhesive resin to be used for the pressure sensitive adhesive layer, the thickness of the pressure sensitive adhesive layer, the method for forming the pressure sensitive adhesive layer, and the like are as described above. The configuration of the release sheet, the thicknesses of the first release sheet and the second release sheet, and the like are as described above.

### Conductive Layer Forming Step

The conductive layer forming step is a step of forming the first conductive layer on the first pressure sensitive adhesive layer in the step (c) of the method for manufacturing a thermoelectric conversion module of the present invention, and is also a step of forming the second conductive layer on the second pressure sensitive adhesive layer in the step (g). For example, this step is a step of forming a metal layer on the pressure sensitive adhesive layer, and processing it into a predetermined pattern to form the conductive layer.

As the first conductive layer and the second conductive layer, the above-described conductive layer is used. In addition, the metal material, metal oxide, and conductive particles used for the conductive layer, the thickness of the conductive layer, the method for forming the conductive layer, and the like are as described above.

### Solder Material Layer Forming Step

The solder material layer forming step is the step (d) of the method for manufacturing a thermoelectric conversion module of the present invention (including the step (h)), and is also a step of forming the solder material layer on the first conductive layer and the second conductive layer.

The solder material layer is used to join the thermoelectric element and the conductive layer.

A solder material constituting the solder material layer may be appropriately selected in consideration of a heat resistance temperature of the material constituting the thermoelectric conversion module, and electrical conductivity and thermal conductivity as a solder material layer. Examples thereof include known materials such as Sn, Sn/Pb alloys, Sn/Ag alloys, Sn/Cu alloys, Sn/Sb alloys, Sn/In alloys, Sn/Zn alloys, Sn/In/Bi alloys, Sn/In/Bi/Zn alloys, Sn/Bi/Pb/Cd alloys, Sn/Bi/Pb alloys, Sn/Bi/Cd alloys, Bi/Pb alloys, Sn/Bi/Zn alloys, Sn/Bi alloys, Sn/Bi/Pb alloys, Sn/Pb/Cd alloys, and Sn/Cd alloys. An alloy such as a 43Sn/57Bi alloy, a 42Sn/58Bi alloy, a 40Sn/56Bi/4Zn alloy, a 48Sn/52 In alloy, or a 39.8Sn/52 In/7Bi/1.2Zn alloy is preferred from the perspective of lead-free and/or cadmium-free, melting point, electrical conductivity, and thermal conductivity. Examples of commercially available solder material products that can be used include the following. For example, a 42Sn/58Bi alloy (available from Tamura Corporation, product name: SAM10-401-27), a 41Sn/58Bi/Ag alloy (available from Nihon Honda Inc., product name: PF141-LT7HO), and the like can be used.

The thickness of the solder material layer (after heating and cooling) is preferably from 1 to 200 μm, more preferably from 5 to 100 μm, and even more preferably from 10 to 50 μm. When the thickness of the solder material layer falls within this range, adhesion with the thermoelectric element and the conductive layer is easily provided.

Examples of the method of coating the solder material include known methods such as stencil printing, screen printing, and dispensing methods. The heating temperatures vary based on, for example, the solder material and the resin film, but heating is typically performed at a temperature ranging from 150 to 280° C. for 1 to 20 minutes.

### Thermoelectric Element Placing Step

The thermoelectric element placing step is the step of (e) of the method for manufacturing a thermoelectric conversion module of the present invention, and is also a step of placing one surface of the thermoelectric element produced in the step (a) on the solder material layer produced in the step (d) and producing the thermoelectric conversion module intermediate 1. For example, this step is a step of, on the solder material layer on the conductive layer, placing one surface of the P-type thermoelectric element and one surface of the N-type thermoelectric element on the upper surface of the corresponding solder material layer.

The arrangement of the P-type thermoelectric elements and the N-type thermoelectric elements may be a combination of the same types or may be a random combination such as “ . . . . NPPN . . . ” or “ . . . . PNPP . . . ” depending on applications. From the viewpoint of theoretically achieving high thermoelectric performance, in the present invention, a plurality of pairs of the P-type thermoelectric element and the N-type thermoelectric element are arranged via electrodes.

The method of placing the thermoelectric element on the solder material layer is not particularly limited, and a known method is used. Examples thereof include a method in which one or a plurality of thermoelectric elements are handled by a chip mounter or the like, aligned using a camera or the like, and placed.

From the viewpoints of handleability, placing precision, and mass producibility, the thermoelectric element is preferably placed using the chip mounter described above.

### Thermoelectric Conversion Module Intermediate 2 Production Step

The thermoelectric conversion module intermediate 2 production step is the step (h) of the method for manufacturing a thermoelectric conversion module of the present invention, and is also a step of forming a solder material layer on the second conductive layer produced in the step (g) to produce the thermoelectric conversion module intermediate 2.

The material used for the solder material layer, the thickness of the solder material layer, the method for forming the solder material layer, and the like are as described above.

### Thermoelectric Conversion Module Precursor Production Step

The thermoelectric conversion module precursor production step is the step (i) of the method for manufacturing a thermoelectric conversion module of the present invention. This step is a step of producing a thermoelectric conversion module precursor by causing the exposed surface of the thermoelectric element of the thermoelectric conversion module intermediate 1 produced in the step (h) and the solder material layer on the second conductive layer of the thermoelectric conversion module intermediate 2 produced in the step (e) to face each other, aligning them so as to form a configuration of a π-type thermoelectric conversion element, and bonding them together. For the bonding, a known method can be used.

### Reflow Treatment Step

The reflow treatment step is the step (j) of the method for manufacturing a thermoelectric conversion module of the present invention, and is also a step of subjecting the thermoelectric conversion module precursor produced in the step (i) to a reflow treatment to form a thermoelectric conversion module from the thermoelectric conversion module precursor. After completion of the step, a thermoelectric conversion module is produced.

The reflow treatment is performed for example by arranging the thermoelectric conversion module precursor in a heating furnace and heating or heating and pressurizing the thermoelectric conversion module precursor. The heating in the reflow treatment depends on the melting temperature of the solder material layer and the like, but is usually performed under an atmosphere of 120 to 350° C. for 1 to 60 minutes, preferably under an atmosphere of 160 to 320° C. for 3 to 40 minutes. The applied pressure is preferably from 0.05 to 10 MPa, more preferably from 0.1 to 5 MPa, and even more preferably from 0.2 to 3 MPa. When heating or heating and pressurizing conditions fall within the above ranges, positional deviation of the thermoelectric element with respect to the conductive layer due to melting of the solder material is suppressed, and joining can be performed with high accuracy.

In another aspect, the method for manufacturing a thermoelectric conversion module of the present invention may include a step of forming a pattern of the first pressure sensitive adhesive layer instead of the step (b) of forming the first pressure sensitive adhesive layer on the release layer of the first release sheet in the steps (a) to (j) described above.

The material used for the first pressure sensitive adhesive layer, the thickness of the first pressure sensitive adhesive layer, the method for forming the pattern on the first pressure sensitive adhesive layer, and the like are as described above.

In the thermoelectric conversion module of the present invention, the first release sheet functions as a support base material during the manufacturing process, and deformation and damage during conveyance and handling can be suppressed, and after the first release sheet and the second release sheet are removed, the thermoelectric conversion module is thinned. Further, since the gap portion consisting of the region between the P-type thermoelectric element and the N-type thermoelectric element is maintained, the thermoelectric conversion module with reduced thermal resistance is produced.

### EXAMPLES

The present invention will now be described in greater detail by way of examples, but the present invention is not limited by these examples.

The thermoelectric modules produced in Examples and Comparative Examples were evaluated for handleability, peel adhesion, release force, and curvature by the following methods.

### (a) Handleability Evaluation

Each of the thermoelectric conversion modules produced in Example 1 and Comparative Example 1 was allowed to freely fall from a height of 50 cm above a resin floor. The electric resistance value (electrical conducting state) between the stripped electrode portions of the thermoelectric conversion module before and after the drop test was measured using a digital high-tester (manufactured by Hioki E.E. Corporation, model name: 3801-50) and evaluated according to the following evaluation criteria.
“Good”: electrical conducting (no change in electric resistance value before and after the test).
“Bad”: no electrical conducting (the electric resistance value changed to infinity after the test).

### (b) Peel Adhesion Evaluation

For each of the ten samples of the thermoelectric conversion modules produced in Example 1 and Comparative Example 1, the first release sheet was removed, and the sample was attached to an SUS plate prepared in advance, and then the second release sheet was removed, and a copper plate was attached to produce a simulated thermoelectric conversion device. The electric resistance value (electrical conducting state) between the stripped electrode portions of the thermoelectric conversion module in the device was measured using a digital high-tester (manufactured by Hioki E.E. Corporation, model name: 3801-50) and evaluated according to the following evaluation criteria.
“Very good”: all the 10 samples conducted electricity.
“Good”: Among the 10 samples, 5 to 9 samples conducted electricity.
“Bad”: Among the 10 samples, 0 to 4 samples conducted electricity.

### (c) Release Force Evaluation

One of the release sheets of each of the thermoelectric conversion modules produced in Example 1 and Comparative Example 1 was removed, and the thermoelectric conversion module was attached and fixed to an SUS plate. Thereafter, the remaining release sheet was removed using a universal tensile tester (Autograph (trade name) AG-IS manufactured by Shimadzu Corporation) at a temperature of 23° C., a peeling angle of 180°, a peeling rate of 300 mm/min, and other conditions in accordance with JIS Z0237:2009, and the load at that time was measured. The results are shown in Table 1.

### (d) Curvature Evaluation

The radius of the circle formed by the sheet when the first release sheet and the second release sheet used in Example 1 were each cut into lengths of 250 mm and widths of 50 mm, and suspended at the center point portion was measured. The first release sheet had R1000. In contrast, the second release sheet did not form a circular shape, with both ends sagging, making measurement impossible.

### Example 1

### Production of Thermoelectric Conversion Module

### (1) Preparation of Thermoelectric Element

A P-type thermoelectric wafer (BiSbTe) and an N-type thermoelectric wafer (BiTe) manufactured by Toyoshima Manufacturing Co., Ltd. were diced to prepare a P-type thermoelectric element and an N-type thermoelectric element each having a rectangular parallelepiped shape with upper and lower surfaces measuring 1 mm×1 mm and a thickness of 300 μm.

### Production of Thermoelectric Conversion Module Semi-Finished Product (Intermediate)

1.0 part by mass (in terms of solid content) of trimethylolpropane-modified trilene diisocyanate (manufactured by Toyo Chem, product name “BHS8515”) and 0.28 part by mass of 3-glycidoxypropyltrimethoxysilane were added to 100 parts by mass of an acrylic polymer with a weight-average molecular weight of 700,000 and containing 47 mass % of butyl acrylate, 47 mass % of 2-ethylhexyl acrylate, 5 mass % of acrylic acid, and 1 mass % of 2-hydroxypropyl acrylate, followed by dilution with ethyl acetate to prepare a coating solution.

The coating liquid was applied onto the release layer of a polyethylene terephthalate release film (manufactured by Lintec Corporation, thickness: 110 μm) serving as the first release sheet using an applicator, dried at 90° C. for 1 minute, and then cured under an environment of 23° C. and 50% RH for 7 days, thereby producing a first pressure sensitive adhesive layer with a thickness of 15 μm. Next, a copper foil (thickness: 30 μm) was attached onto the first pressure sensitive adhesive layer, and a first conductive layer made of the copper foil was patterned using a photolithography process. A Sn—Bi solder material (manufactured by Koki Co., Ltd., product name: Lead-Free Solder Paste, thickness: 20 μm) was then applied at predetermined positions on the resulting first conductive layer. Subsequently, 80 pairs of P-type and N-type thermoelectric elements, prepared in step (1), were arranged alternately and electrically connected in series on the first conductive layer and soldered by heating at 190° C. for 1 minute, thereby producing a thermoelectric conversion module intermediate 1.

### (3) Formation of Thermoelectric Conversion Module Precursor

Next, the coating liquid was applied onto the release layer of a polyethylene terephthalate release film (manufactured by Lintec Corporation, thickness: 50 μm) serving as the second release sheet, which was then subjected to the same treatment to form a second pressure sensitive adhesive layer with a thickness of 15 μm.

Next, a copper foil (thickness: 30 μm) was attached onto the second pressure sensitive adhesive layer, and a second conductive layer made of the copper foil was patterned using a photolithography process. A Sn—Bi solder material (manufactured by Koki Co., Ltd., product name: Lead-Free Solder Paste, thickness: 20 μm) was then applied at predetermined positions on the resulting second conductive layer, thereby producing a thermoelectric conversion module intermediate 2. A thermoelectric conversion module precursor was produced by overlaying the solder on the second conductive layer surface of the intermediate 2 and the exposed surface side of the thermoelectric element of the thermoelectric conversion module intermediate 1 produced in step (2) so as to form a configuration of a π-type thermoelectric conversion element.

### (4) Production of Thermoelectric Conversion Module

Next, the thermoelectric conversion module precursor was heated at 190° C. for 1 minute using a hot plate (manufactured by AS-ONE, model name: HS-2SA), thereby joining the thermoelectric element layer on the second conductive layer side and the second conductive layer. Thereafter, a ceramic weight was placed thereon, and a heat-compression treatment was performed under conditions of 0.3 MPa and 100° C. for 10 minutes, thereby producing a thermoelectric conversion module shown in FIG. 1 in which a gap was formed between the P-type thermoelectric elements and the N-type thermoelectric elements and even the boundary between the thermoelectric element and the conductive layer was covered with the pressure sensitive adhesive layer (Configuration A; including the release film).

### Comparative Example 1

A thermoelectric conversion module of Comparative Example 1 (Configuration B; including a release film) was produced in the same manner as in Example 1 except that the first release sheet used in Example 1 was changed to the second release sheet used in Example 1.

Table 1 shows the evaluation results of the handleability, the peel adhesion, the release force, and the curvature of the thermoelectric conversion modules produced in Example 1 and Comparative Example 1.

TABLE 1

| | | | | | | | | | Handleability | | |
|---|---|---|---|---|---|---|---|---|---|---|---|
| | | First release sheet | | | Second release sheet | | | Difference | Presence or absence of | | |
| | Thermoelectric | | | Release | | | Release | in release | electrical conducting | | |
| | conversion | | | force | | | force | force | | After | After |
| | module | Thickness | | (mN/25 | Thickness | | (mN/25 | (mN/25 | | drop | peel |
| | Configuration | [μm] | Curvature | mm) | [μm] | Curvature | mm) | mm) | Initial | test | adhesion |
| Example 1 | A | 110 | R1000 | 120 | 50 | — | 680 | 560 | Good | Good | Very |
| | | | | | | | | | | | good |
| Comparative | B | 50 | — | 680 | 50 | — | 680 | 0 | Good | Bad | Bad |
| Example 1 | | | | | | | | | | | |

Table 1 shows that in the thermoelectric conversion module of Example 1 satisfying the provisions of the present invention, the first release sheet functions as a support base material during the manufacturing process, and deformation and damage during conveyance and handling are suppressed as compared with the thermoelectric conversion module of Comparative Example 1 not satisfying the provisions of the present invention.

### INDUSTRIAL APPLICABILITY

According to the thermoelectric conversion module of the present invention, there is provided the release sheet which functions as a support base material during the manufacturing process and in which deformation and damage during conveyance and handling are suppressed. Therefore, the release sheet can be used in the manufacturing process of the thermoelectric conversion module. The resulting thermoelectric conversion module becomes thinner as compared with the product of the related art when the release sheet is removed. Therefore, for examples, in the field of the electronics, as cooling applications, the thermoelectric conversion module is applied, for example, to temperature control of central processing units (CPU) used in a smartphone, a variety of computers, and the like, image sensors such as a complementary metal oxide semiconductors (CMOS) and charge coupled devices (CCD), and further, micro electro mechanical systems (MEMS), a variety of sensors such as light receiving elements, and the like.

### REFERENCE SIGNS LIST

1: Thermoelectric conversion module
2: Thermoelectric element layer
2p: P-type thermoelectric element
2n: N-type thermoelectric element
2a: Second surface of thermoelectric element layer 2
2b: First surface of thermoelectric element layer 2
3a: Second pressure sensitive adhesive layer
3b: First pressure sensitive adhesive layer
4a: Second conductive layer
4b: First conductive layer
5a: Second release sheet
5b: First release sheet
11: Thermoelectric conversion module
12: Thermoelectric element layer
12p: P-type thermoelectric element
12n: N-type thermoelectric element
12a: Second surface of thermoelectric element layer 2
12b: First surface of thermoelectric element layer 2
13a: Second pressure sensitive adhesive layer
13b: First pressure sensitive adhesive layer
14a: Second conductive layer
14b: First conductive layer
15a: Second release sheet
15b: First release sheet

1. A thermoelectric conversion module comprising:
a thermoelectric element layer in which a P-type thermoelectric element and an N-type thermoelectric element are arranged alternately and electrically connected in series;
a first conductive layer provided on a first surface of the thermoelectric element layer;
a first pressure sensitive adhesive layer provided on a surface of the first conductive layer on a side opposite to a surface on the thermoelectric element layer side; and
a first release sheet provided on a surface of the first pressure sensitive adhesive layer on a side opposite to a surface on the first conductive layer side, wherein
a curvature of the first release sheet is R1000 or greater when the first release sheet is cut to a length of 250 mm and suspended at a center in a length direction.

2. The thermoelectric conversion module according to claim 1, further comprising a second conductive layer provided on a second surface opposite to the first surface of the thermoelectric element layer.

3. The thermoelectric conversion module according to claim 2, further comprising a second pressure sensitive adhesive layer provided on a surface of the second conductive layer on a side opposite to a surface on the thermoelectric element layer side.

4. The thermoelectric conversion module according to claim 3, further comprising a second release sheet provided on a surface of the second pressure sensitive adhesive layer on a side opposite to a surface on the second conductive layer side.

5. The thermoelectric conversion module according to claim 4, wherein a release force of the first release sheet is greater or smaller than a release force of the second release sheet.

6. The thermoelectric conversion module according to claim 1, wherein the first pressure sensitive adhesive layer is a pattern layer formed from a pressure sensitive adhesive composition, and a surface of the pattern layer having the same shape as that of a surface of the first conductive layer is in surface contact with the surface of the first conductive layer.

7. The thermoelectric conversion module according to claim 1, wherein the first pressure sensitive adhesive layer is a solid layer formed from a pressure sensitive adhesive composition, and a surface of a partial region of the solid layer is in surface contact with a surface of the first conductive layer.

8. The thermoelectric conversion module according to claim 1, further comprising a gap portion consisting of a region between the P-type thermoelectric element layer and the N-type thermoelectric element layer.
